(19) United States
(12) Patent Application Publication
(10) Pub. No.: US 2010/0203699 A1
(43) Pub. Date: Aug. 12, 2010

(54) Method of forming semiconductor device

(75) Inventor: Ken Tokashiki, Seongnam-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/654,390

(22) Filed: Dec. 18, 2009

(30) Foreign Application Priority Data
Feb. 9, 2009 (KR) 10-2009-0010229

(51) Int. Cl. H01L 21/02

(52) U.S. Cl. 438/381; 257/E21.008

(57) ABSTRACT

Provided may be a method of forming a semiconductor device. The method may include performing a pre-anisotropic etching process on a dielectric layer exposed by a guide opening, performing an etch-back process on a mask layer and performing a post anisotropic etching process through a guide opening using the etched mask layer as an etching mask.

### CROSS-REFERENCE TO RELATED APPLICATIONS

This U.S. non-provisional patent application claims priority under 35 U.S.C. § 119 to Korean Patent Application No. 10-2009-0010229, filed on Feb. 9, 2009, in the Korean Intellectual Property Office (KIPO), the entire contents of which are incorporated herein by reference.

### BACKGROUND

Example embodiments provide methods of forming a semiconductor device, and more particularly, methods of forming a semiconductor device including an opening.

Semiconductor devices are relatively small, perform multi-functions and/or have a lower manufacturing cost. Semiconductor devices may include various unit elements, for example, a MOS transistor, a resistor, a capacitor and/or an interconnection. The unit elements may be embodied in various types of patterns, for example, an interconnection, a dopant region, a device isolation pattern, a hole and/or an electrode.

However, as the integration of semiconductor devices increases, problems may be generated. As a result, manufacturing semiconductor devices becomes more difficult. For example, a density of a pattern being formed within a unit area to obtain a higher integration increases and a vertical size of a pattern also increases. Thus, a photolithography process and an etching process to embody patterns become more difficult. For example, as a line width of a pattern is reduced, a margin of a photolithography process to define a pattern may be reduced, and as a vertical size of a pattern increases, an etching depth increases, thereby reducing a margin of an etching process. As the trend is towards higher integration of semiconductor devices, studies for manufacturing a semiconductor device suitable for higher integration are being performed.

### SUMMARY

Example embodiments of inventive concepts provide methods of forming a semiconductor device. The methods may include sequentially forming a dielectric layer and a mask layer on a substrate; penetrating the mask layer to expose the dielectric layer by forming a guide opening; performing a pre-anisotropic etching process on the exposed dielectric layer using the guide opening as an etching mask; etching the mask layer using an etch-back process; and performing a post anisotropic etching process through the opening using the etched mask layer as an etching mask.

### BRIEF DESCRIPTION OF THE DRAWINGS

Example embodiments of inventive concepts will be more clearly understood from the following detailed description taken in conjunction with the accompanying drawings. FIGS. 1-5E represent non-limiting, example embodiments of inventive concepts as described herein

FIGS. 1A through 1H are cross sectional views illustrating a method of forming a semiconductor device in accordance with example embodiments of the inventive concepts.

FIG. 2 is a flow chart illustrating a method of forming an opening in a dielectric layer in a method of forming a semiconductor device in accordance with example embodiments of the inventive concepts.

FIG. 3 is a cross sectional view illustrating a method of forming a semiconductor device in accordance with example embodiments of the inventive concepts.

FIG. 4 is an experiment graph illustrating a characteristic of an opening formed by a method of forming a semiconductor device in accordance with example embodiments of the inventive concepts.

FIGS. 5A through 5E are cross sectional views illustrating a method of forming a semiconductor device in accordance with example embodiments of the inventive concepts.

It should be noted that these Figures are intended to illustrate the general characteristics of methods, structure and/or materials utilized in certain example embodiments of inventive concepts and to supplement the written description provided below. These drawings are not, however, to scale and may not precisely reflect the precise structural or performance characteristics of any given embodiment, and should not be interpreted as defining or limiting the range of values or properties encompassed by example embodiments of inventive concepts. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

Various example embodiments of inventive concepts will be described more fully hereinafter with reference to the accompanying drawings, in which some example embodiments of inventive concepts may be illustrated. Example embodiments of inventive concepts may, however, be embodied in many different forms and should not be construed as limited to example embodiments of inventive concepts set forth herein. Rather, these example embodiments of inventive concepts may be provided so that this disclosure will be thorough and complete, and will fully convey the scope of example embodiments of inventive concepts to those skilled in the art. In the drawings, the sizes and relative sizes of layers and regions may be exaggerated for clarity.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments of inventive concepts.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments of inventive concepts. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of inventive concepts are described herein with reference to cross-sectional illustrations that are schematic illustrations of idealized embodiments (and intermediate structures) of example embodiments of inventive concepts. As such, variations from the shapes of the illustrations as a result, for example, of manufacturing techniques and/or tolerances, are to be expected. Thus, example embodiments of inventive concepts should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments of inventive concepts.

Unless otherwise defined, all terms (including technical and scientific terms) used herein have the same meaning as commonly understood by one of ordinary skill in the art to which example embodiments of inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

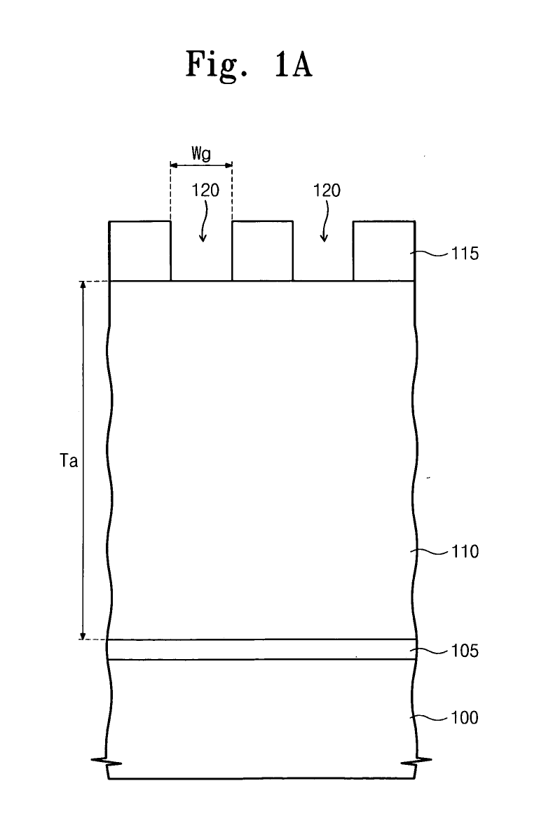

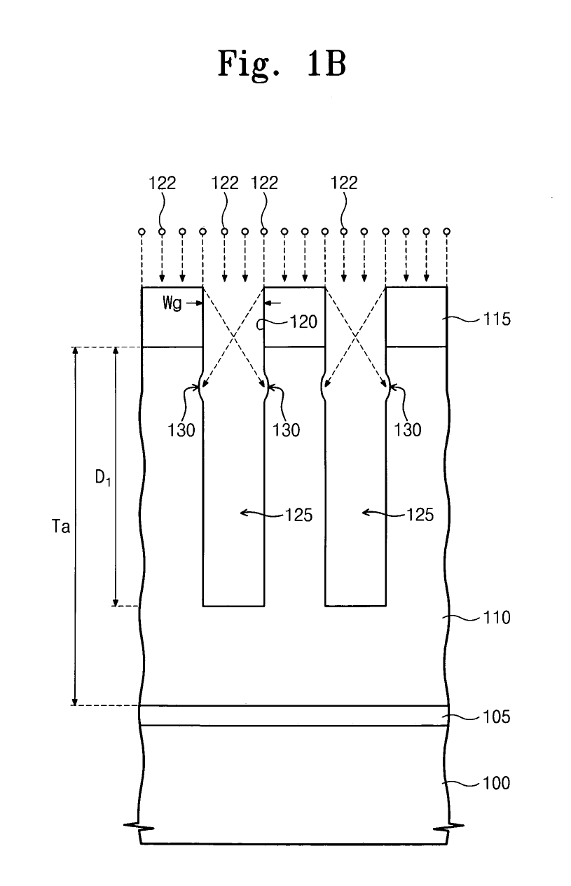

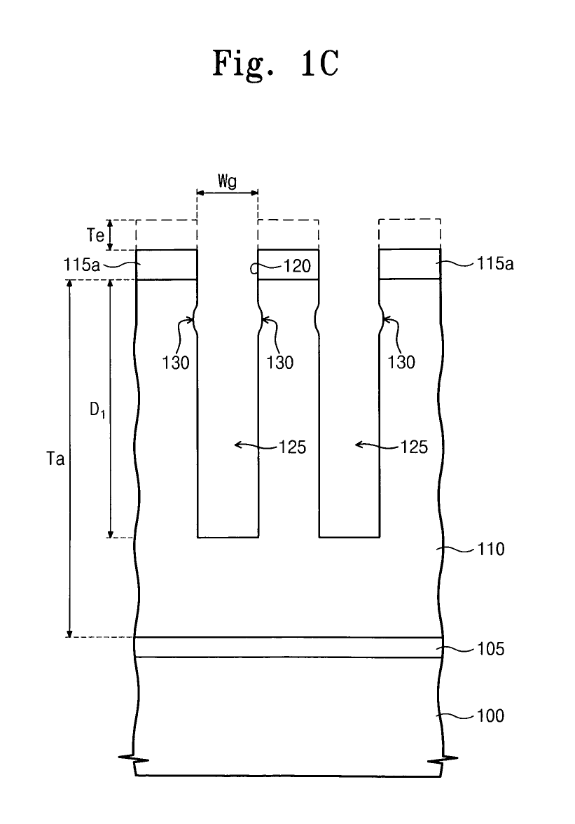

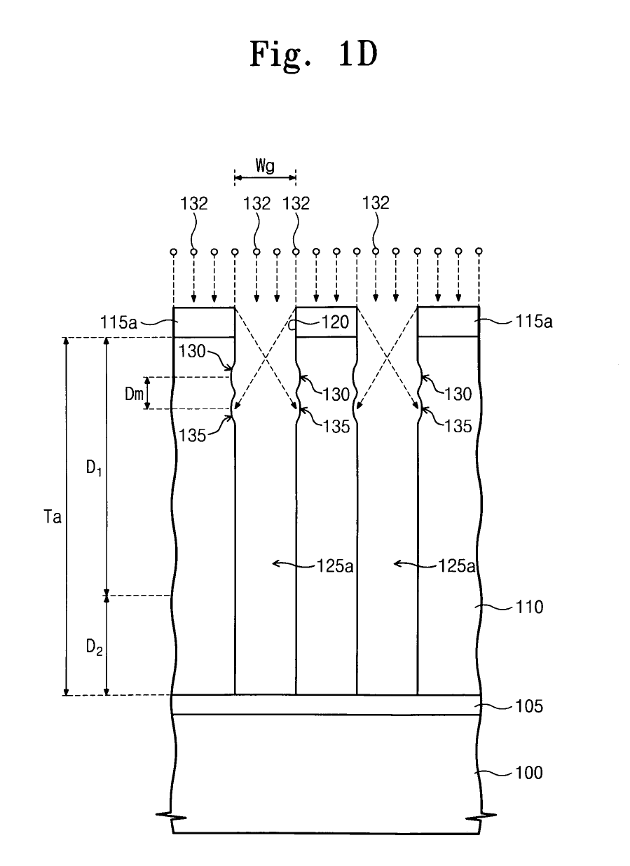

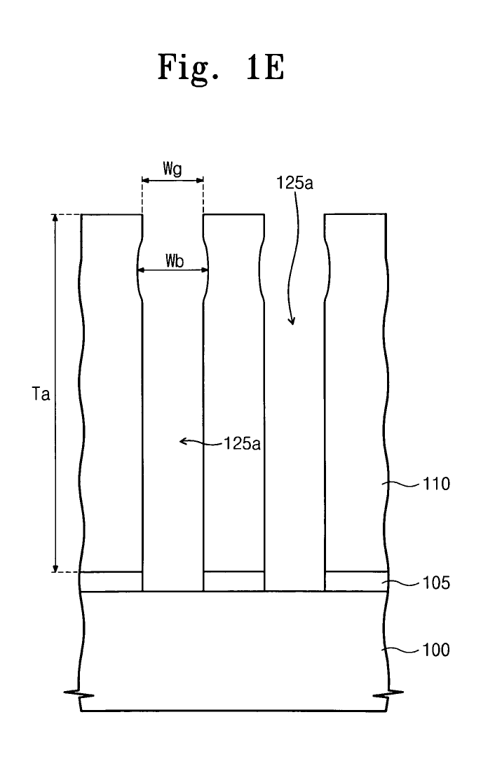

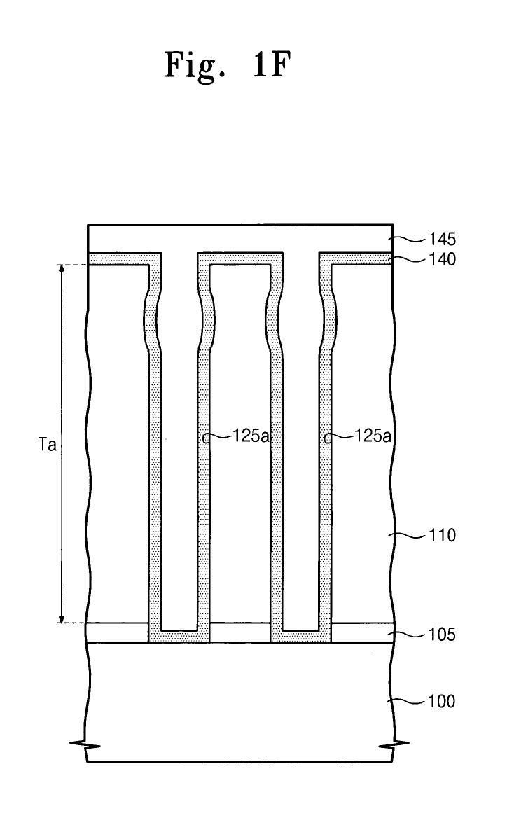

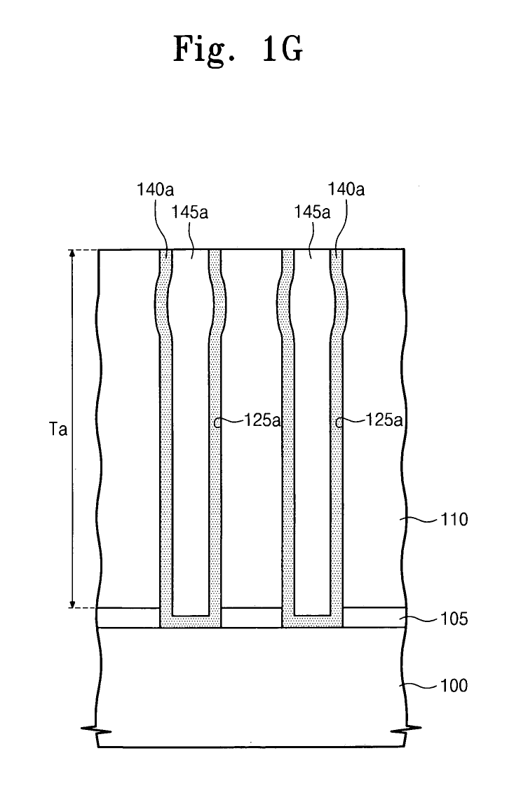

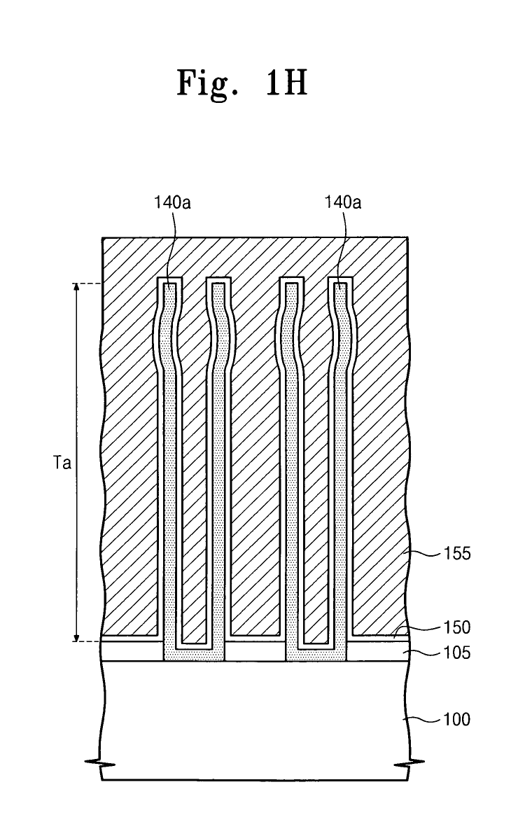

FIGS. 1A through 1H are cross sectional views illustrating a method of forming a semiconductor device in accordance with example embodiments of the inventive concepts. Referring to FIG. 1A, an etch stop layer 105 may be formed on a substrate 100. The substrate 100 may include a semiconductor substrate including a semiconductor material. For example, the substrate 100 may include a silicon substrate, a germanium substrate, a silicon-germanium substrate or a compound semiconductor substrate. Also, the substrate 100 may further include a conductor. The conductor may be a dopant region formed in a semiconductor substrate or a conductive pattern (e.g., an interconnection or a contact plug) formed on a semiconductor substrate. The etch stop layer 105 may be formed on the conductor. The etch stop layer 105 may be omitted.

A dielectric layer 110 may be formed on the etch stop layer 105. The dielectric layer 110 may be single layered or multi layered. The dielectric layer 110 may include at least one selected from a group consisting of an oxide, a nitride, an oxynitride, a carbide, a low dielectric material of MSQ (Methyl Silses Quioxane) system and a low dielectric material of HSQ (Hydro Silses Quioxane). The etch stop layer 105 may be formed of an insulating material having an etching selectivity with respect to the dielectric layer 110. For example, the dielectric layer 110 may be formed of oxide, and the etch stop layer 105 may include at least one of nitride and oxynitride. Alternatively, the dielectric layer 110 may be formed of at least one of nitride and oxynitride, and the etch stop layer 105 may be formed of oxide. However, the inventive concept may not be limited to those described above. The dielectric layer 110 may include other dielectric materials having an etching selectivity with respect to the etch stop layer 105. Also, the etch stop layer 105 may include some other insulating materials having etching selectivity with respect to the dielectric layer 110.

A mask layer 115 may be formed on the dielectric layer 110. The mask layer 115 may include a material having an etching selectivity with respect to the dielectric layer 110. For example, the mask layer 115 may include an organic material. However, example embodiments of the inventive concepts may not be limited to those described above. The mask layer 115 may be formed of at least one of polysilicon, polygermanium, polysilicon-germanium, a nitride and an oxynitride.

The mask layer 115 may be patterned to form a guide opening 120 exposing the dielectric layer 110. The guide opening 120 may have a hole-shape. When the guide opening 120 has a hole-shape, the guide opening 120 may have a circle shape, an oval shape or a polygonal shape in a plane view. Alternatively, the guide opening 120 may have a groove shape extending along one direction parallel to a top surface of the substrate 100. A plurality of guide openings 120 may be formed to be separated from one another. A thickness (Ta) of the dielectric layer 110 may be greater than a width (Wg) of the guide opening 120.

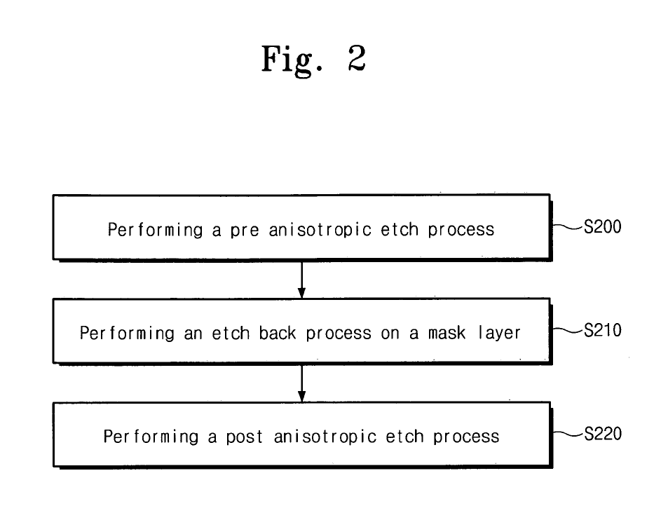

A method of forming an opening (125a illustrated in FIG. 1D) penetrating the dielectric layer 110 may be described with reference to FIGS. 1B through 1D and a flow chart of FIG. 2. FIG. 2 is a flow chart illustrating a method of forming an opening in a dielectric layer in a method of forming a semiconductor device in accordance with example embodiments of the inventive concepts.

Referring to FIGS. 1B and 2, a pre-anisotropic etching process may be performed on the dielectric layer 110 exposed by the guide opening 120 using the mask layer 115 as an etching mask (S200). When the pre-anisotropic etching process is performed, an etching rate of the dielectric layer 110 by the pre-anisotropic etching process may be greater than an etching rate of the mask layer 115 by the pre-anisotropic etching process because the mask layer 115 may be used as an etching mask. For example, the etching rate of the dielectric layer 110 by the pre-anisotropic etching process may be about 15 to about 30 times the etching rate of the mask layer 115 by the pre-anisotropic etching process. However, example embodiments of the inventive concepts may not be limited to those described above.

A process gas used in the pre-anisotropic etching process includes a first etching gas. The first etching gas may be ionized to generate first etching ions 122. The dielectric layer 110 exposed by the guide opening 120 may be etched by the first etching ions 122 to form an etched region 125. The etched region 125 may include an inner sidewall and a bottom surface. A portion of the first etching ions 122 may be scattered by the mask layer 115 to be focused on a first region 130 of the inner sidewall of the etched region 125. For example, the portion of the first etching ions 122 scattered by a top corner and/or an inner sidewall of the guide opening 120 may be focused on the first region 130. Thus, the first region 130 of the inner sidewall of the etched region 125 may be etched.

The process gas of the pre-anisotropic etching process may further include a passivation gas. The passivation gas may form a passivation polymer on the inner sidewall of the etched region 125. An etching degree of the first region 130 caused by the scattered first etching ions 122 may be reduced by the passivation polymer. For example, the passivation gas may include at least one of COS and SO₂.

A first etched depth (D1, for example, a depth of the etched region 125) of the dielectric layer 110 etched by the pre-anisotropic etching process may be smaller than the thickness (Ta) of the dielectric layer 110. Accordingly, a portion of the dielectric layer 110 may remain under the bottom surface of the etched region 125.

According to example embodiments of the inventive concepts, the first etched depth (D1) may be smaller than 17 times the width (Wg) of the guide opening 120. For example, the first etched depth (D1) may be greater than 10 times the width (Wg) of the guide opening 120 and smaller than 16 times the width (Wg) of the guide opening 120. However, the inventive concepts may not be limited to those described above.

Referring to FIGS. 1C and 2, after the pre-anisotropic etching process (S200) is performed, an etch-back process may be performed on the mask layer 115 (S210). Thus, the mask layer 115 may be etched so that a thickness of the mask layer 115 may be reduced. After the etch-back process is performed (S210), the etched mask layer 115a may remain on the dielectric layer 110. For example, a portion of the mask layer 115 may be etched by the etch-back process. The etched mask layer 115a may still have the guide opening 120. The etch-back process may be anisotropic. Thus, the thickness of the mask layer 115 may be reduced by the etch-back process while the width (Wg) of the guide opening 120 may not be substantially reduced. A reference character “Te” represents a thickness (Te) of the mask layer 115 etched by the etch-back process.

The dielectric layer 110 may have an etching selectivity with respect to the mask layer 115 while performing the etch-back process (S210). For example, an etching rate of the mask layer 115 by the etch-back process may be far greater than an etching rate of the dielectric layer 110 by the etch-back process. For example, the etching rate of the mask layer 115 by the etch-back process may be about 15 to about 30 times the etching rate of the dielectric layer 110 by the etch-back process. However, example embodiments of the inventive concepts may not be limited to those described above. When the mask layer 115 includes an organic material, a process gas used in the etch-back process may include at least one of O₂, O₃, N₂, NH₃, He, Ar, Ne, Kr, Xe, COS, CO₂, CO and H₂S.

In the case that a polymer (e.g., the passivation polymer and/or a polymer of an etching by-product) is formed in the etched region 125 when the pre-anisotropic etching process is performed, the polymer in the etched region 125 may be etched by the etch-back process.

Referring to FIGS. 1D and 2, a post anisotropic etching process may be performed through the guide opening 122 using the etched mask layer 115a as an etching mask (S220). An etching rate of the dielectric layer 110 by the post anisotropic etching process may be far greater than an etching rate of the etched mask layer 115a by the post anisotropic etching process. For example, the etching rate of the dielectric layer 110 by the post anisotropic etching process may be about 15 to about 30 times the etching rate of the etched mask layer 115a by the post anisotropic etching process. However, example embodiments of the inventive concepts may not be limited to those described above.

The remainder of the dielectric layer 110 under the etched region 125 may be etched by the post anisotropic etching process. All of the remainder of the dielectric layer 110 under the etched region 125 may be etched by the post anisotropic etching process. The dielectric layer 110 may be etched by a second etched depth (D2) by the post anisotropic etching process. The second etched depth (D2) may be a value that subtracts the first etched depth (D1) from the thickness (Ta) of the dielectric layer 110. The second etched depth (D2) may be smaller than 17 times the width (Wg) of the guide opening 120. The post anisotropic etching process may include a process of etching the remainder of the dielectric layer 110 and an over-etching process. The etched region 125a of the dielectric layer 110 by the pre-anisotropic etching process and the post anisotropic etching process may penetrate the dielectric layer 110.

A process gas used in the post anisotropic etching process may include a second etching gas. The second etching gas may be ionized to generate second etching ions 132. A portion of the second etching ions 132 may be scattered by the etched mask layer 115a to be focused on a second region 135 of the inner sidewall of the etched region 125a. Thus, the second region 135 may be etched. A portion of the second etching ions 132 may be scattered by a top corner and/or an inner sidewall of the guide opening 120 in the etched mask layer 115a. A thickness of the mask layer 115 may be reduced by the etch-back process, so the second region 135 may be disposed at a position moved from the first region 130. More specifically, the second region 135 may be disposed below the first region 130. A distance between the first region 130 and the second region 135 may be controlled by an etched thickness (Te of FIG. 1C) of the mask layer 115 etched by the etch-back process. For example, a distance (Dm) between a center of the first region 130 and a center of the second region 135 may be substantially equal to the etched thickness (Te of FIG. 1C) of the mask layer 115.

An overlap of a lower edge of the first region 130 and an upper edge of the second region 135 may be desirably minimized or reduced or the first and second regions 130 and 135 may be separate from each other. The etched thickness (Te) of the mask layer 115 by the etch-back process may be greater than about 25 nm.

The process gas of the post anisotropic etching process may further include a passivation gas (e.g., COS and/or SO₂). A passivation polymer may be formed on at least an inner wall of the etched region 125a by the passivation gas of the post anisotropic etching process. Thus, an etching degree of the second region 135 may be reduced.

When the etched region 125a of the dielectric layer 110 by the pre-anisotropic etching process and post anisotropic etching process penetrates the dielectric layer 110, the etched region 125a may be defined as an opening 125a penetrating the dielectric layer 110. The opening 125a may expose a portion of the etch stop layer 105. A shape of the opening 125a may be determined by a shape of the guide opening 120. For example, when the guide opening 120 has a hole-shape, the opening 125a may be formed to have a hole-shape. According to example embodiments of inventive concepts, when the guide opening 120 has a groove shape, the opening 125a may be formed to have a groove shape.

As described above, when a polymer remains in the etched region 125, the polymer may be etched by the etch-back process. Thus, a reduction of a width of the etched portion (e.g., a bottom portion of the opening 125a) by the post anisotropic etching process may be minimized or reduced. If the post anisotropic etching process is performed under the condition that a polymer exists in the etched region 125, the polymer may function as an etching mask. However, as described above, the polymer in the etched region 125 may be etched by the etch-back process and a reduction of a width of a bottom portion of the opening 125 may be minimized or reduced. When the dielectric layer 110 is formed of one dielectric material, the second etching gas of the post anisotropic etching process may be equal to the first etching gas of the pre-anisotropic etching process.

According to example embodiments of the inventive concepts, the post anisotropic etching process may include only an over-etching process. In example embodiments of the inventive concepts, the first etched depth (D1) by the pre-anisotropic etching process may be substantially equal to the thickness (Ta) of the dielectric layer 110. For example, the pre-anisotropic etching process may correspond to a main etching process substantially etching the dielectric layer 110 and the post anisotropic etching process may correspond to the over-etching process. In example embodiments of the inventive concepts, the thickness (Ta) of the dielectric layer 110 may be smaller than 17 times the width (Wg) of the guide opening 120. When the first depth (D1) is substantially equal to the thickness (Ta) of the dielectric layer 110, the second etched depth (D2) may be substantially zero.

Referring to FIG. 1E, the etch stop layer 105 exposed by the opening 125a may be removed. The etch stop layer 105 exposed by the opening 125a may be removed by an anisotropic etching or isotropic etching. The opening 125a successively penetrates the dielectric layer 110 and the etch stop layer 105 by removing the exposed etch stop layer 105. Thus, the opening 125a may expose the conductor of the substrate 100.

After or before removing the etch stop layer 105 exposed by the opening 125a, the etched mask layer 115a may be removed. A width of an upper end of the opening 125a may be substantially equal to the width (Wg) of the guide opening 120. The first and second regions 130 and 135 formed in the inner wall of the opening 125a may be defined as a bowing region. The bowing region may be formed to have a gentle curved surface shape by cleaning processes performed after the opening 125a may be formed. A width (Wb) of the bowing region may be greater than a width of a portion of the opening 125a adjacent to below and/or over the bowing region. The width (Wb) of the bowing region may be greater than the width (Wg) of the upper end of the opening 125a.

According to the method of forming a semiconductor device described above, before performing the post anisotropic etching process (S220), the etch-back process may be performed to reduce a thickness of the mask layer 115. Thus, the second region 135 by the post anisotropic etching process moves from the first region 130 by the pre-anisotropic etching process. As a result, the width (Wb) of the bowing region may be reduced. For example, regions that the scattered etching ions may be concentrated on may be dispersed on the inner wall of the etched region of the dielectric layer 110 by performing the etch-back process on the mask layer 115 (S210). Accordingly, the width (Wb) of the bowing region may be reduced.

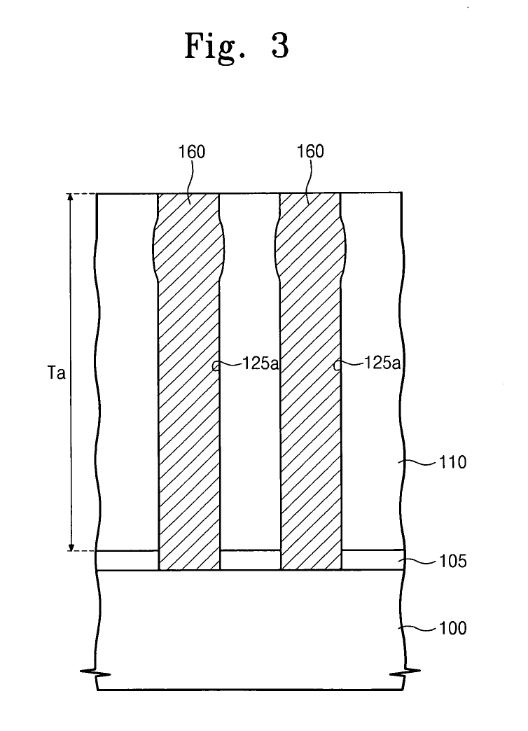

If the etch-back process is not performed, etching ions etching the dielectric layer 110 may be concentrated on one portion of the inner wall of the etched region. In example embodiments of the inventive concepts, the width of the bowing region increases, so that a space between adjacent openings 125a may be reduced or adjacent openings 125a may be connected to each other. As a result, a space between conductive patterns formed in adjacent openings 125a respectively may be reduced or the conductive patterns may be shorted. However, according to example embodiments of the inventive concepts, the etch-back process may be performed (S210) between the pre-anisotropic etching process and the post anisotropic etching process to reduce the width (Wg) of the bowing region. For example, a space between the adjacent openings 125a may be increased. As a result, a short between the adjacent conductive patterns (140a of FIG. 1G or 160 of FIG. 3) formed in the adjacent openings 125a respectively may be prevented or reduced. The opening 125a of FIG. 1E may correspond to a capacitor hole to form a capacitor. That case may be described with reference to FIGS. 1F through 1H.

Referring to FIG. 1F, after the etch stop layer 105 exposed by the opening 125a is removed, a lower conductive layer 140 may be conformally formed on an entire surface of the substrate 100. The lower conductive layer 140 may be conformally formed on an inner wall and a bottom surface of the opening 125a and on a top surface of the dielectric layer 110. The lower conductive layer 140 may include at least one of doped semiconductor (e.g., doped silicon, doped germanium and doped silicon-germanium), conductive metal nitride (e.g., titanium nitride and tantalum nitride) and conductive metal oxide (e.g., iridium oxide). A sacrificial layer 145 filling the opening 125a may be formed on the lower conductive layer 140.

Referring to FIG. 1G, the sacrificial layer 145 and the lower conductive layer 140 may be planarized down to a top surface of the dielectric layer 110. As a result, a lower electrode 140a and a sacrificial pattern 145a that are sequentially stacked in the opening 125a may be formed.

Referring to FIG. 1H, the sacrificial pattern 145a and the dielectric layer 110 may be removed to expose an inner surface and an outer surface of the lower electrode 140a. The etch stop layer 105 under the dielectric layer 100 may remain on the substrate 100. The inner surface of the lower electrode 140a may be a surface exposed by removing the sacrificial pattern 145a. The outer surface of the lower electrode 140a may be a surface exposed by removing the dielectric layer 110. The sacrificial pattern 145a may be formed of a material having an etching rate equal to or greater than that of the dielectric layer 110. For example, the sacrificial pattern 145a may be formed of an oxide, e.g., USG and SOG. The sacrificial pattern 145a and the dielectric layer 110 may be removed by a wet etching.

Subsequently, a capacitor dielectric layer 150 may be formed on a surface of the lower electrode 140a and an upper electrode 155 covering a surface of the lower electrode 140a may be formed on the capacitor dielectric layer 150. The capacitor dielectric layer 150 may include at least one of an oxide, a nitride and a high dielectric material. The high dielectric material may include an insulating metal nitride, e.g., a hafnium nitride and an aluminum nitride. The upper electrode 155 may include at least one of a conductive material, e.g., semiconductor (e.g., doped silicon, doped germanium and doped silicon-germanium), metal (e.g., titanium, tantalum and platinum), conductive metal nitride (e.g., titanium nitride and tantalum nitride layer) and a conductive metal oxide (e.g., an iridium oxide). The opening 125a may be a different shape which is not a capacitor hole described with reference to FIG. 3.

FIG. 3 is a cross sectional view illustrating a method of forming a semiconductor device in accordance with example embodiments of the inventive concepts. Referring to FIG. 3, the opening 125a may be formed to be a contact hole or a groove. In example embodiments of the inventive concepts, after removing the etch stop layer 105 exposed by the opening 125a, a conductive layer filling the opening 125a may be formed on an entire surface of the substrate 100 and the conductive layer may be planarized down to a top surface of the dielectric layer 110 to form a conductive pattern 160 in the opening 125a. When the opening 125a is formed to be a contact hole, the conductive pattern 160 may be formed to be a contact plug. As an alternative, when the opening 125a is formed to be a groove, the conductive pattern 160 may be formed to be an interconnection.

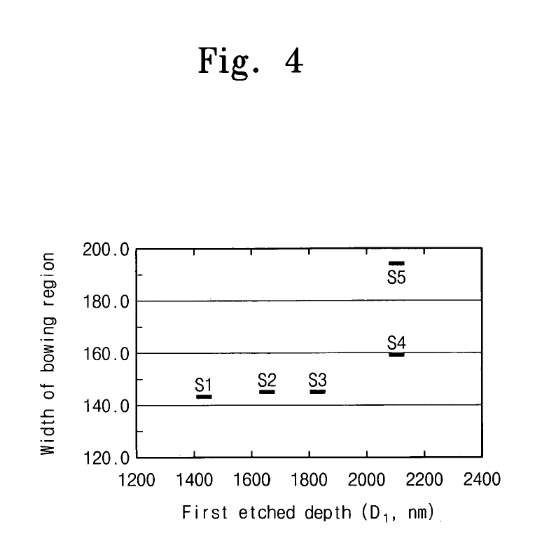

An experiment may be performed to verify a characteristic in accordance with a method of forming a semiconductor device according to example embodiments of the inventive concepts. That may be described in detail with reference to an experiment graph of FIG. 4.

FIG. 4 is an experiment graph illustrating a characteristic of an opening formed by a method of forming a semiconductor device in accordance with example embodiments of the inventive concepts. Referring to FIG. 4, a sample 1 (S1), a sample 2 (S2), a sample 3 (S3), a sample 4 (S4), and a sample 5 (S5) were prepared for an experiment. Thicknesses of the etch stop layers 105 of the samples 1 through 5 (S1, S2, S3, S4 and S5) were formed to be about 100 nm. Thicknesses of the dielectric layers 110 of the samples 1 through 5 (S1, S2, S3, S4 and S5) were formed to be about 2100 nm. The dielectric layers 110 of samples 1 through 5 (S1, S2, S3, S4 and S5) were formed of silicon oxide.

Widths of the guide openings of samples 1 through 5 (S1, S2, S3, S4 and S5) were formed to be about 120 nm. The mask layers 115 of samples 1 through 5 (S1, S2, S3, S4 and S5) were formed of an organic material. The pre-anisotropic etching process, the etch-back etching process and the post anisotropic etching process were sequentially performed on the samples 1 through 4 (S1, S2, S3 and S4). An oxygen gas was used as an etching gas of the etch-back etching process of the samples 1 through 4 (S1, S2, S3 and S4). An etched thickness of the mask layer 115 of the samples 1 through 4 (S1, S2, S3 and S4) were all about 50 nm. As an alternative, the etch-back etching process was not performed on the sample 5 (S5). For example, the sample 5 (S5) etched the dielectric layer 110 under the guide opening using one anisotropic etching process.

The samples 1 through 4 (S1, S2, S3 and S4) were formed to have different first etched depths (D1) from one another. For example, a first etched depth (D1) and a second etched depth (D2) of the sample 1 (S1) were about 1430 nm and about 670 nm respectively. The first etched depth (D1) of the sample 1 (S1) corresponds to about 12 times the width of the guide opening of the sample 1 (S1). A first etched depth (D1) and a second etched depth (D2) of the sample 2 (S2) were about 1650 nm and about 450 nm respectively. The first etched depth (D1) of the sample 2 (S2) corresponds to about 14 times the width of the guide opening of the sample 2 (S2). A first etched depth (D1) and a second etched depth (D2) of the sample 3 (S3) were about 1830 nm and about 270 nm respectively. The first etched depth (D1) of the sample 3 (S3) corresponds to about 15.1 times the width of the guide opening of the sample 3 (S3). A first etched depth (D1) and a second etched depth (D2) of the sample 4 (S4) were about 2080 nm and about 20 nm respectively. The first etched depth (D1) of the sample 4 (S4) corresponds to about 17.3 times the width of the guide opening of the sample 4 (S4).

Widths of bowing regions of the samples 1 through 5 (S1, S2, S3, S4 and S5) were measured and the measured widths were illustrated in FIG. 4. As illustrated in FIG. 4, a width of bowing region of the sample 5 (S5) (the etch-back etching process and the post anisotropic etching process were not performed on it) was represented as about 194 nm. As an alternative, widths of bowing regions of the samples 1 through 4 (S1, S2, S3 and S4) were measured to be below about 160 nm. Accordingly, the widths of bowing regions of the samples 1 through 4 (S1, S2, S3 and S4) were reduced.

Also, widths of bowing regions of the samples 1 through 3 (S1, S2 and S3) were about 143 nm, about 145 nm and about 145 nm., respectively. For example, the widths of bowing regions of the samples 1 through 3 (S1, S2 and S3) were close to each other. Alternatively, a width of bowing region of the sample 4 (S4) was about 160 nm and was greater than those of the samples 1 through 3 (S1, S2 and S3). The first etched depth (D1) of the sample 4 (S4) was about 17.3 times the width of the guide opening of the sample 4 (S4). Therefore, when the first etched depth (D1) is more than about 17 times the width (Wg) of the guide opening, the width (Wb) of the bowing region may increase. Thus, when the first etched depth (D1) is less than about 17 times the width (Wg) of the guide opening, the width (Wb) of the bowing region may be stably reduced.

A second experiment was performed on the etched thickness (Te of FIG. 1C) of the mask layer by an etch-back etching process. The widths (Wg) of guide openings, the thickness of dielectric layer, the first etched depths (D1) and the post anisotropic etching processes which are the same as the foregoing experiment were applied to the samples for the second experiment. The samples for the second experiment had the different etched thicknesses (Te of FIG. 1C) of a mask layer by an etch-back etching process from one another. As a result of the second experiment, when the etched thicknesses (Te of FIG. 1C) of mask layer were less than about 25 nm, widths of the bowing regions were gently changed, and when the etched thicknesses (Te of FIG. 1C) of mask layer were greater than 25 nm, the widths of the bowing regions were abruptly reduced. In the light of these, when the etched thicknesses (Te of FIG. 1C) of a mask layer by the etch-back etching process are greater than about 25 nm, widths of the bowing regions may be sufficiently reduced.

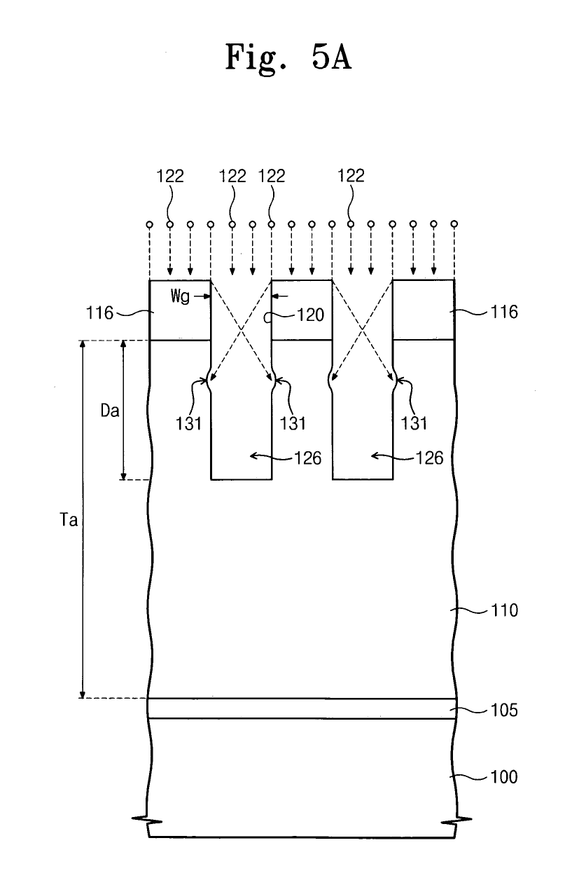

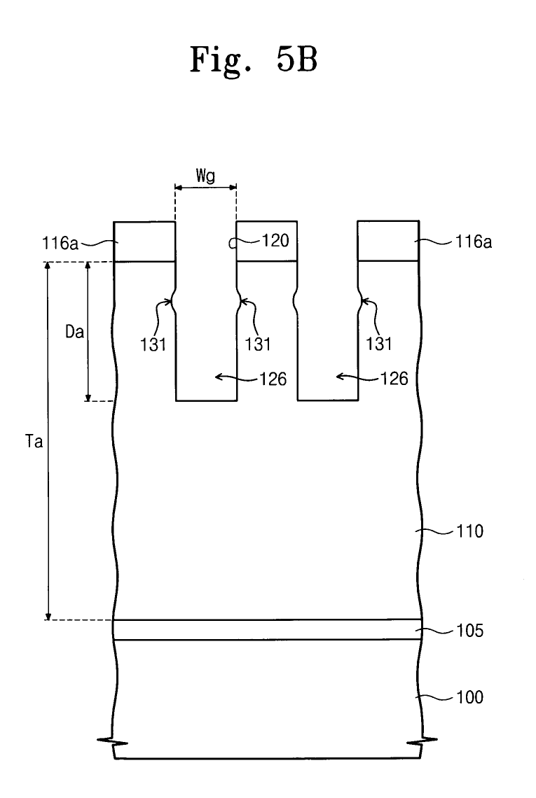

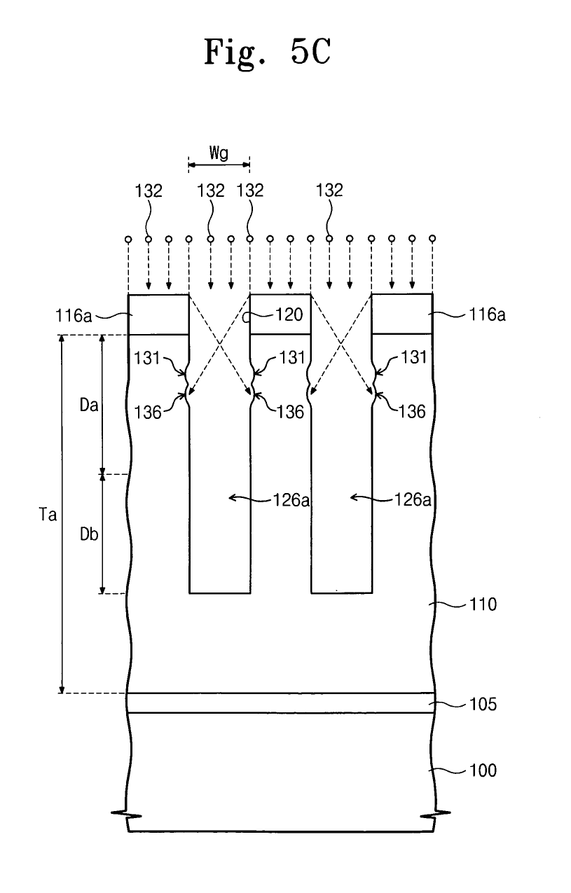

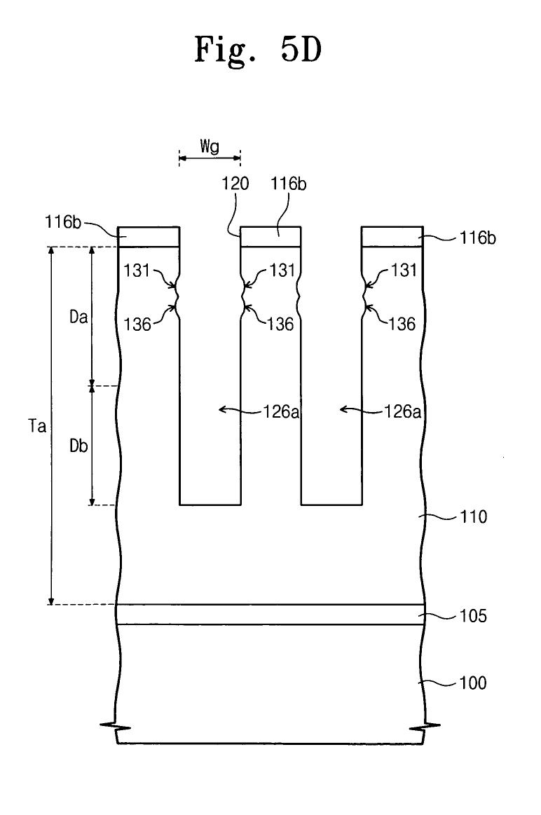

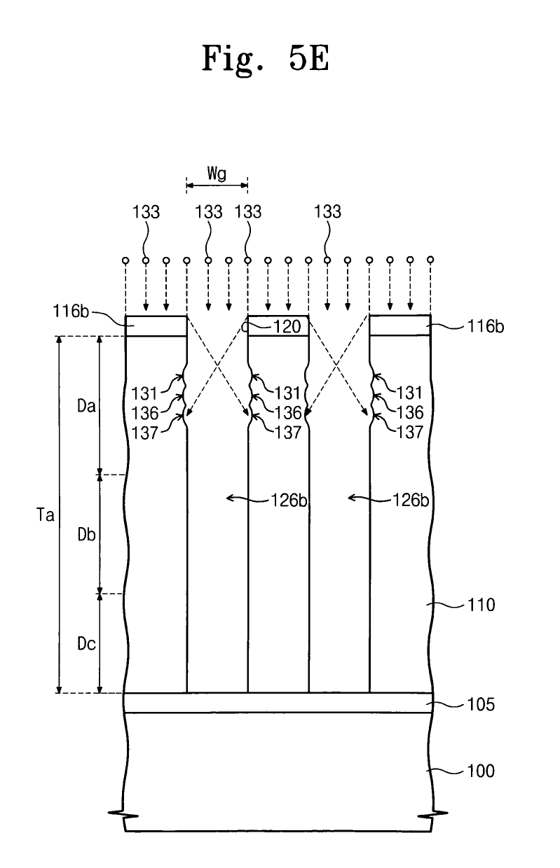

In example embodiments of the inventive concepts, another method of forming an opening penetrating a dielectric layer 110 may be disclosed. In example embodiments of the inventive concepts, the performance of the etch-back process (S210) and the performance of the post anisotropic etching process (S220) may become one cycle to be repeatedly performed in at least two cycles. Elements in example embodiments of inventive concepts illustrated in FIGS. 5A through 5E that are similar or identical to example embodiments of inventive concepts illustrated in FIGS. 1A-1H have the same reference numerals.

FIGS. 5A through 5E are cross sectional views illustrating a method of forming a semiconductor device in accordance with example embodiments of the inventive concepts. Referring to FIG. 5A, a dielectric layer 110 may be formed on a substrate 100. Before the dielectric layer 110 is formed, an etch stop layer 105 may be formed on the substrate 100. In example embodiments of the inventive concepts, the dielectric layer 110 may be formed on the etch stop layer 105. A mask layer 116 may be formed on the dielectric layer 110 and may be patterned to form a guide opening 120. The mask layer 116 may be formed of the same material as the mask layer 115 of FIG. 1A. A thickness of the mask layer 116 may be greater than that of the mask layer 115 of FIG. 1A. Example embodiments of the inventive concepts may not be limited to those described above. The guide opening 120 may have a similar shape to the guide opening 120 in FIG. 1A. A thickness of the dielectric layer 110 may be greater than a width (Wg) of the guide opening 120.

A pre-anisotropic etching process may be performed on the dielectric layer 110 exposed by the guide opening 120 using the mask layer 116 as an etching mask. A process gas used in the pre-anisotropic etching process may include a first etching gas. First etching ions 122 generated by ionizing the first etching gas may be anisotropically proceed to etch the exposed dielectric layer 110. Accordingly, a first etched region 126 may be formed in the dielectric layer 110 under the guide opening 120. A portion of the first etching ions 122 may be scattered by a top corner and/or an inner wall of the guide opening 120 to be concentrated on a first region 131 of an inner wall of the first etched region 126. Thus, the first region 131 may be etched. A first etched depth (Da) by the pre-anisotropic etching process may be smaller than the thickness of the dielectric layer 110. Thus, a portion of the dielectric layer 110 remains under a bottom surface of the first etched region 126. The first etched depth (Da) may be smaller than about 17 times the width (Wg) of the guide opening 120.

The process gas used in the pre-anisotropic etching process may further include a passivation gas (e.g., at least one of COS and SO₂). A passivation polymer may be formed in the first etched region 126 by the passivation gas. The etching amount of the first region 131 may be reduced by the passivation polymer.

Referring to FIG. 5B, subsequently, the mask layer 116 may be etched by a first etch-back process to reduce a thickness of the mask layer 116. A first etched mask layer 116a remains on the dielectric layer 110. For example, a portion of the mask layer 116 may be etched by the first etch-back process. The first etch-back process may be an anisotropic etching. Thus, a width of the mask layer 116 may be reduced while the width (Wg) of the guide opening 120 is not substantially changed. When the first etch-back process is performed, the dielectric layer 110 has an etching selectivity with respect to the mask layer 116. For example, an etch rate of the mask layer 116 by the first etch-back process may be greater than an etch rate of the dielectric layer 110 by the first etch-back process. For example, the etch rate of the mask layer 116 by the first etch-back process may be about 15 to about 30 times the etch rate of the dielectric layer 110 by the first etch-back process. When the mask layer 116 include an organic material, the process gas used in the first etch-back process may include at least one of O₂, O₃, N₂, NH₃, He, Ar, Ne, Kr, Xe, COS, CO₂, CO and H₂S. An etched thickness of the mask layer 116 by the first etch-back process may be greater than about 25 nm. When a polymer (e.g., a passivation polymer and/or an etching residual polymer) exists in the first etched region 126, the polymer in the first etched region 126 may be etched by the first etch-back process.

Referring to FIG. 5C, a first post anisotropic process may be performed through the guide opening 120 using the first etched mask layer 116a as an etching mask. Accordingly, the dielectric layer 110 under the first etched region 126 may be etched to form a second etched region 126a. The second etched region 126a means an etched region formed by sequentially performing the pre-anisotropic etching process, the first etch-back process and the post anisotropic etching process. A process gas used in the first post anisotropic etching process may include a second etching gas. The second etching gas may be ionized to generate second etching ions 132. The dielectric layer 110 under the first etched region 126 may be etched by the anisotropic second etching ions 132.

A portion of the second etching ions 132 may be scattered by a top corner and/or an inner wall of the guide opening 120 penetrating the first etched mask layer 116a to be concentrated on a second region 136 of an inner wall of the second etched region 126a. Thus, the second region 136 may be etched. A thickness of the mask layer 116 may be reduced by the first etch-back process, so the second region 136 may be disposed at a position downwardly moved from the first region 131.

The process gas used in the first post anisotropic etching process may further include a passivation gas (at least one of COS and SO₂). A passivation polymer may be formed in the second etched region 126a by the passivation gas used in the first post anisotropic etching. The etching amount of the second region 136 may be reduced by the passivation polymer. A second etched depth (Db) by the first post anisotropic etching process may be smaller than a thickness (Ta) of the dielectric layer 110. The second etched depth (Db) may be smaller than about 17 times the width (Wg) of the guide opening 120. A portion of the dielectric layer 110 may remain under a bottom surface of the second etched region 126a.

Referring to FIG. 5D, a second etch-back process may be performed on the first etched mask layer 116a. Accordingly, a thickness of the first etched mask layer 116a may be reduced. The mask layer 116 etched by the second etch-back process may be defined as a second etched mask layer 116b. The second etched mask layer 116b remains on the dielectric layer 110. The second etch-back process may be an anisotropic etching process. Thus, the width (Wg) of the guide opening 120 penetrating the second etched mask layer 116b may not be substantially changed.

When the second etch-back process is performed, the dielectric layer 110 has an etching selectivity with respect to the first etched mask layer 116a. An etch rate of the first etched mask layer 116a by the second etch-back process may be greater than an etch rate of the dielectric layer by the second etch-back process. For example, the etch rate of the first etched mask layer 116a by the second etch-back process may be about 15 to about 30 times the etch rate of the dielectric layer 110 by the second etch-back process.

When the first etched mask layer 116a include an organic material, a process gas used in the second etch-back process may include at least one of O₂, O₃, N₂, NH₃, He, Ar, Ne, Kr, Xe, COS, CO₂, CO and H₂S. The process gas used in the second etch-back process may be equal to the process gas used in the first etch-back process. An etched thickness of the first etched mask layer 116a by the second etch-back process may be greater than about 25 nm. When a polymer (e.g., a passivation polymer and/or an etching residual polymer) exists in the second etched region 126a, the polymer in the second etched region 126a may be etched by the second etch-back process.

Referring to FIG. 5E, a second post anisotropic process may be performed through the guide opening 120 using the second etched mask layer 116b as an etching mask. Accordingly, a remainder of the dielectric layer 110 under the second etched region 126a may be etched. A third etched region 126b formed by sequentially performing the pre-anisotropic etching process, the first etch-back process, the first post anisotropic etching process, the second etch-back process and the second post anisotropic etching process may penetrate the dielectric layer 110 to expose the etch stop layer 105. In example embodiments of the inventive concepts, the second post anisotropic etching process may include an over etching process.

The process gas used in the post anisotropic etching gas may include a third etching gas. The third etching gas may be ionized to generate third etching ions 133. The anisotropic third etching ions 133 may etch the dielectric layer 110 under the second etched region 126a. A portion of the third etching ions 133 may be scattered by a top corner and/or an inner wall of the guide opening 120 of the second etched mask layer 116b. The scattered third etching ions 133 may be concentrated on a third region 137 of an inner wall of the third etched region 126b. The third region 137 may be disposed at a position moved from the second region 136 due to the second etched mask layer 116b formed by the second etch-back process. The third region 137 may be disposed at a position downwardly moved from the second region 136.

The process gas used in the second post anisotropic etching process may include a passivation gas (e.g., at least one of COS and SO₂). A passivation polymer may be formed in the third etched region 126b by the passivation gas to reduce the etching amount of the third region 137. A third etched depth (Dc) by the second post anisotropic etching process may be smaller than about 17 times the width (Wg) of the guide opening 120. The first, second and third etched depths (Da, Db and Dc) may be different from one another or equal to one another.

When the dielectric layer 110 is formed of one dielectric material, the first, second and third gases used in the pre, first, post and second post anisotropic etching processes respectively may be equal to one another. In example embodiments of the inventive concepts, the second post anisotropic etching process may include only an over etching process and the second etched depth (Dc) may be substantially zero.

The third etched region 126b penetrating the dielectric layer 110 may be defined as an opening 126b penetrating the dielectric layer 110. The opening 126b may be formed to have a hole-shape or a groove shape according to a shape of the guide opening 120. A process of removing the etch stop layer 105 exposed to the opening 126b and processes after the removing process may be performed using the same method as the methods described with reference to FIGS. 1E through 1H or as the methods described with reference to FIGS. 1E and 3.

According to a method of forming a semiconductor device in accordance with example embodiments of the inventive concepts, the etch-back process and the post anisotropic process constitute a cycle. After performing the pre-anisotropic etching process, the cycle may be repeatedly performed two times, thereby forming the opening 126b. However, example embodiments of the inventive concepts may not be limited to those described above. The cycle may be repeatedly performed three times. In example embodiments of the inventive concepts, the last performed one among the post anisotropic etching processes may include an over etching process. The last performed post anisotropic etching process may include only an over etching process.

According to the method of formation in accordance with example embodiments of the inventive concepts, the etch-back process and the post anisotropic etching process constitute a cycle and the cycle may be repeatedly performed at least two times, thereby forming the opening 126b. Accordingly, regions on which scattered etching ions are concentrated may be dispersed to more than three regions. Accordingly, the etching amount of each of the regions may be reduced. As a result, a bowing phenomenon of the opening 126b may be minimized or reduced.

According to example embodiments of the inventive concepts, before performing the post anisotropic etching process, the mask layer may be etched by the etch-back process to reduce a thickness of the mask layer. Thus, a bowing phenomenon of an opening penetrating the dielectric layer may be minimized or reduced. For example, when the pre-anisotropic etching process is performed, a portion of etching ions may be scattered to be concentrated on a first region of an inner wall of an etched region of the dielectric layer, and when the post anisotropic etching process is performed, a portion of etching ions may be scattered to be concentrated on a second region of an inner wall of an etched region of the dielectric layer. Before the post anisotropic etching process is performed, a thickness of the mask layer may be reduced by the etch back process. Therefore, the second region may be disposed at a position moved from the first region. As a result, the regions on which scattered ions are concentrated may be dispersed to minimize or reduce a bowing phenomenon of the opening, thereby embodying a highly integrated semiconductor device.

The foregoing may be illustrative of example embodiments of inventive concepts and may be not to be construed as limiting thereof. Although a few example embodiments of inventive concepts have been described, those skilled in the art will readily appreciate that many modifications may be possible in the example embodiments of inventive concepts without materially departing from the novel teachings and advantages of example embodiments of inventive concepts. Accordingly, all such modifications are intended to be included within the scope of the claims. Therefore, it is to be understood that the foregoing is illustrative of various example embodiments of inventive concepts and is not to be construed as limited to the specific example embodiments of inventive concepts disclosed, and that modifications to the disclosed example embodiments of inventive concepts, as well as other example embodiments of inventive concepts, are intended to be included within the scope of the appended claims.

What is claimed is:

1. A method of forming a semiconductor device comprising:
sequentially forming a dielectric layer and a mask layer on a substrate;
penetrating the mask layer to expose the dielectric layer by forming a guide opening;
performing a pre-anisotropic etching process on the exposed dielectric layer using the guide opening as an etching mask;
etching the mask layer using an etch-back process; and
performing a post anisotropic etching process through the opening using the etched mask layer as an etching mask.

2. The method of claim 1, wherein etching the mask layer using an etch-back process includes reducing a thickness of the mask layer.

3. The method of claim 1, wherein performing the pre-anisotropic etching on the exposed dielectric layer includes scattering a portion of etching ions by the mask layer such that the etching ions are concentrated on a first region of an inner wall of an etched region of the dielectric layer.

4. The method of claim 3, wherein performing the post anisotropic etching on the exposed dielectric layer includes scattering a portion of the etching ions by the mask layer such that the etching ions are concentrated on a second region of the inner wall of the etched region of the dielectric layer, the second region at a position separate from the first region.

5. The method of claim 1, wherein the dielectric layer has an etching selectivity with respect to the mask layer while the, mask layer is etched by the etch-back process.

6. The method of claim 3, wherein a portion of the dielectric layer remains under the etched region of the dielectric layer after performing the pre-anisotropic etching process, and the post anisotropic etching process is performed on the remaining portion of the dielectric layer.

7. The method of claim 6, wherein etching the mask layer using an etch-back process and performing the post anisotropic etching process are repeatedly performed at least two times.

8. The method of claim 7, wherein the last of the post anisotropic etching processes performed includes an over etching process.

9. The method of claim 1, wherein an etching gas used in the pre-anisotropic etching process is identical to an etching gas used in the post anisotropic etching process.

10. The method of claim 1, wherein the mask layer comprises an organic material.

11. The method of claim 3, wherein the etch-back process further comprises etching a polymer in the etched region of the dielectric layer.

12. The method of claim 1, wherein an etched depth of the dielectric layer etched by the pre-anisotropic etching process is smaller than 17 times a width of the guide opening.

13. The method of claim 1, wherein a thickness of the dielectric layer is greater than a width of the guide opening.

14. The method of claim 1, further comprising:
forming an etch stop layer on the substrate before forming the dielectric layer, the etch stop layer formed of an insulating material having an etching selectivity with respect to the dielectric layer.

15. The method of claim 4, wherein a width of an upper end of an opening of the etched region of the dielectric layer is equal to a width of the guide opening.

16. The method of claim 15, wherein the first and second regions of the inner wall of the etched region of the dielectric layer are a bowing region, the width of the bowing region being greater than the width of the upper end of the opening of the etched region of the dielectric layer.

17. The method of claim 15, further comprising:
forming a lower conductive layer on the substrate, the inner wall and a bottom surface of the opening of the etched region of the dielectric layer and on a top surface of the dielectric layer; and
forming a sacrificial layer on the lower conductive layer and filling the opening of the etched region of the dielectric layer.

18. The method of claim 17, further comprising:
planarizing the sacrificial layer and the lower conductive layer down to a top surface of the dielectric layer in order to form a sacrificial pattern and a lower electrode sequentially stacked in the opening of the etched region of the dielectric layer.

19. The method of claim 18, further comprising:
removing the sacrificial pattern and the dielectric layer to expose an inner surface and an outer surface of the lower electrode by a wet etching process;
forming a capacitor dielectric layer on a surface of the lower electrode; and
forming an upper electrode around the capacitor dielectric layer 150.

20. The method of claim 4, wherein a distance between a center of the first region and a center of the second region is equal to an etched thickness of the mask layer.
